(19) United States
(12) Patent Application Publication
(10) Pub. No.: US 2014/0145201 A1
(43) Pub. Date: May 29, 2014

(54) METHOD AND SYSTEM FOR GALLIUM NITRIDE VERTICAL JFET WITH SEPARATED GATE AND SOURCE

(71) Applicant: AVOGY, INC., San Jose, CA (US)

(72) Inventors: Hui Nie, Cupertino, CA (US); Andrew P. Edwards, San Jose, CA (US); David P. Bour, Cupertino, CA (US); Isik C. Kizilyalli, San Francisco, CA (US); Richard J. Brown, Los Gatos, CA (US); Thomas R. Prunty, Sunnyvale, CA (US)

(73) Assignee: AVOGY, INC., San Jose, CA (US)

(21) Appl. No.: 13/689,574

(22) Filed: Nov. 29, 2012

(51) Int. Cl. H01L 29/78; H01L 29/20; H01L 21/36

(52) U.S. Cl. CPC H01L 29/7827; H01L 21/36; H01L 29/2003
USPC 257/76; 438/478; 257/615

(57) ABSTRACT

A semiconductor structure includes a III-nitride substrate and a first III-nitride epitaxial layer of a first conductivity type coupled to the III-nitride substrate. The semiconductor structure also includes a first III-nitride epitaxial structure of the first conductivity type coupled to the first III-nitride epitaxial layer and a second III-nitride epitaxial structure of the first conductivity type coupled to the first III-nitride epitaxial structure. The semiconductor structure further includes a second III-nitride epitaxial layer coupled to the first III-nitride epitaxial structure. The second III-nitride epitaxial layer is of a second conductivity type and is not electrically connected to the second III-nitride epitaxial structure.

### BACKGROUND OF THE INVENTION

Power electronics are widely used in a variety of applications. Power electronic devices are commonly used in circuits to modify the form of electrical energy, for example, from ac to dc, from one voltage level to another, or in some other way. Such devices can operate over a wide range of power levels, from milliwatts in mobile devices to hundreds of megawatts in a high voltage power transmission system. Despite the progress made in power electronics, there is a need in the art for improved electronics systems and methods of operating the same.

### SUMMARY OF THE INVENTION

The present invention relates generally to electronic devices. More specifically, the present invention relates to forming a vertical junction field-effect transistor (JFET). Merely by way of example, the invention has been applied to methods and systems for manufacturing normally-off vertical JFETs using gallium nitride (GaN) based epitaxial layers. In a particular embodiment, an etchback of a regrown gate material is utilized to provide electrical isolation between a gate region and a source region of the vertical JFET. The methods and techniques can be applied to a variety of compound semiconductor systems including n-channel and p-channel vertical JFETs, which can provide either normally-off or normally-on functionality.

According to an embodiment of the present invention, a method for fabricating a controlled switching device is provided. The method includes providing a III-nitride substrate and forming a first III-nitride epitaxial layer coupled to the III-nitride substrate. The first III-nitride epitaxial layer is characterized by a first dopant concentration. The method also includes forming a second III-nitride epitaxial layer coupled to the first III-nitride epitaxial layer. The second III-nitride epitaxial layer has a second dopant concentration of the same type and less than or equal to the first dopant concentration. The method further includes forming a third III-nitride epitaxial layer coupled to the second III-nitride epitaxial layer. The third III-nitride epitaxial layer has a third dopant concentration of the same type and greater than the first dopant concentration. Additionally, the method includes removing at least a portion of the third III-nitride epitaxial layer and at least a portion of the second III-nitride epitaxial layer to form a channel region of the second III-nitride epitaxial layer, forming an epitaxial layer of an opposite type from the first III-nitride epitaxial layer coupled to the channel region, removing at least a portion of the epitaxial layer of the opposite type, and forming one or more metallic structures electrically coupled to device terminals.

According to another embodiment of the present invention, a semiconductor structure is provided. The semiconductor structure includes a III-nitride substrate and a first III-nitride epitaxial layer of a first conductivity type coupled to the III-nitride substrate. The semiconductor structure also includes a first III-nitride epitaxial structure of the first conductivity type coupled to the first III-nitride epitaxial layer and a second III-nitride epitaxial structure of the first conductivity type coupled to the first III-nitride epitaxial structure. The semiconductor structure further includes a second III-nitride epitaxial layer coupled to the first III-nitride epitaxial structure. The second III-nitride epitaxial layer is of a second conductivity type and is not electrically connected to the second III-nitride epitaxial structure.

According to a particular embodiment of the present invention, a vertical III-nitride field effect transistor is provided. The vertical III-nitride field effect transistor includes a drain comprising a first III-nitride material and a drain contact electrically coupled to the drain. The vertical III-nitride field effect transistor also includes a drift region comprising a second III-nitride material coupled to the drain and disposed adjacent to the drain along a vertical direction and a channel region comprising a third III-nitride material coupled to the drift region. The vertical III-nitride field effect transistor further includes a gate region at least partially surrounding the channel region, a gate contact electrically coupled to the gate region, a source coupled to the channel region and electrically isolated from the gate region, and a source contact electrically coupled to the source. The channel region is disposed between the drain and the source along the vertical direction such that current flow during operation of the vertical III-nitride field effect transistor is along the vertical direction.

Numerous benefits are achieved by way of the present invention over conventional techniques. For example, embodiments of the present invention reduce leakage currents and improve the ability to withstand the application of high voltages in comparison with conventional designs. These and other embodiments of the invention, along with many of its advantages and features, are described in more detail in conjunction with the text below and attached figures.

### BRIEF DESCRIPTION OF THE DRAWINGS

FIGS. 1A-1B are simplified cross-sectional diagrams illustrating the operational functionality of a vertical JFET according to an embodiment of the present invention;

FIGS. 2-8 are simplified cross-sectional diagrams illustrating the fabrication of a vertical JFET with separated source and drain regions according to an embodiment of the present invention; and

FIG. 9 is a simplified flowchart illustrating a method of fabricating a vertical JFET with separated source and gate regions according to an embodiment of the present invention.

### DETAILED DESCRIPTION OF SPECIFIC EMBODIMENTS

Embodiments of the present invention relate to electronic devices. More specifically, the present invention relates to forming a vertical junction field-effect transistor (JFET). Merely by way of example, the invention has been applied to methods and systems for manufacturing normally-off vertical JFETs using gallium nitride (GaN) based epitaxial layers. In a particular embodiment, an etchback of a regrown gate material is utilized to provide electrical isolation between a gate region and a source region of the vertical JFET. The methods and techniques can be applied to a variety of compound semiconductor systems including n-channel and p-channel vertical JFETs, which can provide either normally-off or normally-on functionality.

GaN-based electronic and optoelectronic devices are undergoing rapid development. Desirable properties associated with GaN and related alloys and heterostructures include high bandgap energy for visible and ultraviolet light emission, favorable transport properties (e.g., high electron mobility and saturation velocity), a high breakdown field, and high thermal conductivity. According to embodiments of the present invention, gallium nitride (GaN) epitaxy on pseudo-bulk GaN substrates is utilized to fabricate vertical GaN-based semiconductor devices not possible using conventional techniques. For example, conventional methods of growing GaN include using a foreign substrate such as silicon carbide (SiC). This can limit the thickness of a usable GaN layer grown on the foreign substrate due to differences in thermal expansion coefficients and lattice constant between the GaN layer and the foreign substrate. High defect densities at the interface between GaN and the foreign substrate further complicate attempts to create vertical devices, including power electronic devices such as JFETs and other field-effect transistors.

Homoepitaxial GaN layers on bulk GaN substrates, on the other hand, are utilized in the embodiments described herein to provide superior properties to conventional techniques and devices. For instance, electron mobility, μ, is higher for a given background doping level, N. This provides low resistivity, p, because resistivity is inversely proportional to electron mobility, as provided by equation (1):

$$ρ = \frac{1}{q μ N} , \qquad ( 1 )$$

where q is the elementary charge.

Another superior property provided by homoepitaxial GaN layers on bulk GaN substrates is high critical electric field for avalanche breakdown. A high critical electric field allows a larger voltage to be supported over smaller length, L, than a material with a lower critical electric field. A smaller length for current to flow together with low resistivity give rise to a lower resistance, R, than other materials, since resistance can be determined by the equation:

$$R = \frac{ρ L}{A} , \qquad ( 2 )$$

where A is the cross-sectional area of the channel or current path.

In general, a tradeoff exists between the physical dimension of a device needed to support high voltage in a device's off-state and the ability to pass current through the same device with low resistance in the on-state. In many cases GaN is preferable over other materials in minimizing this tradeoff and maximizing performance. In addition, GaN layers grown on bulk GaN substrates have low defect density compared to layers grown on mismatched substrates. The low defect density will give rise to superior thermal conductivity, less trap-related effects such as dynamic on-resistance, and better reliability.

Among the vertical device structures contemplated is a vertical JFET. Depending on doping levels, physical dimensions, conductivity type (e.g., n-type or p-type materials), and other factors, vertical JFETs can be designed to have normally-off or normally-on functionality. A normally-off vertical JFET is particularly useful due to its ability to prevent current flow if no voltage is applied to the gate, which can serve as, among other things, a safety feature for vertical JFETs used in power applications.

A normally-off vertical JFET can be created in various ways. For example, an n-type current path from source to drain can be gated on either side by p+ gates. With sufficiently low background doping, and high positive charge due to high hole concentration in the p+ gates, the channel can be depleted of carriers, or pinched off at zero bias. When a positive voltage is applied to the gate(s), the channel can be re-opened to turn the device on. Thus, in embodiments of the present invention, the vertical JFET is referred to as a vertical junction field effect transistor since the current flows vertically between the source and drain through the gated region.

In addition to the ability to support high-voltage, low-resistance JFET applications, the GaN vertical JFETs described herein can differ from traditional vertical JFETs in other ways. For example, other semiconductors used to manufacture vertical JFETs, such as SiC can be utilized, altering the mode of manufacture. Furthermore, the use of GaN epitaxial layers can allow for non-uniform dopant concentrations as a function of thickness within the various layers of the vertical JFET, which can optimize the performance of the device.

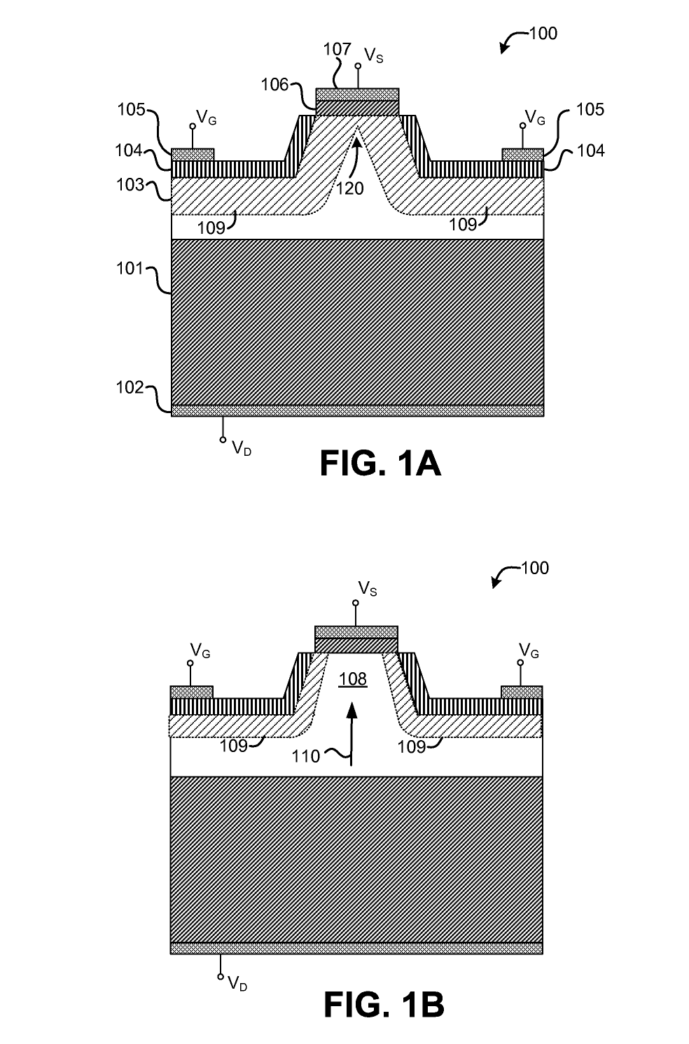

FIGS. 1A-1B are simplified cross-sectional diagrams illustrating the operational functionality of a vertical JFET 100 according to an embodiment of the present invention. Referring to FIG. 1A, a drain is provided using substrate 101. According to the embodiment of the present invention illustrated in FIG. 1A, the substrate 101 (i.e., the drain) is an n-type GaN substrate, but the present invention is not limited to this particular material. In other embodiments, substrates with p-type doping are utilized. Additionally, although a GaN substrate is illustrated in FIG. 1A, embodiments of the present invention are not limited to GaN substrates. Other III-V materials, in particular, III-nitride materials, are included within the scope of the present invention and can be substituted not only for the illustrated GaN substrate, but also for other GaN-based layers and structures described herein. As examples, binary III-V (e.g., III-nitride) materials, ternary III-V (e.g., III-nitride) materials such as InGaN and AlGaN, and quaternary III-V (e.g., III-nitride) materials such as AlInGaN are included within the scope of the present invention. Additionally, embodiments can use materials having an opposite conductivity type to provide devices with different functionality. For example, embodiments provided herein focus on the formation of a JFET with an n-type drain and channel regions. However, a p-type JFET can be formed by using materials with opposite conductivity (e.g., substituting p-type materials for n-type materials, and vice versa) in a similar manner as will be evident to one of skill in the art.

Coupled to the substrate 101 forming the drain, is a drift region 103 of n-type GaN material. The drift region 103 provides a medium through which current can flow in the device's on-state in a vertical direction from the drain to a channel region 108 coupled to the drift region 103. In the off-state, the drift region provides a medium for supporting the electric field created by the voltage gradient between the source or gate and the drain. Although not illustrated, one or more buffer layers can be utilized between the substrate 101 and the drift region 103, as well as between other layers as appropriate to the particular application. The channel region 108 also can comprise an n-type GaN material that is as wide as possible to minimize added resistance when the vertical JFET 100 is turned on, but narrow enough to provide adequate current pinch off when the vertical JFET 100 is turned off. The channel region 108 is coupled to a source 106 comprising a heavily-doped n-type GaN material.

At least partially surrounding the channel region 108 is a p-type GaN material forming a gate 104 region, which can be coupled to at least a portion of the drift region 103 as shown. The p-type GaN material of the gate 104 and the n-type materials of the channel region 108 and drift region 103 form a p-n junction with corresponding depletion regions 109. Finally, contacts 102, 105, and 107, formed from one or more layers of electrical conductors including a variety of metals can be provided on the drain 101, gate 104, and source 106, respectively, to electrically couple the vertical JFET 100 to an electrical circuit (not illustrated).

The operation of the vertical JFET 100 is described as follows. FIG. 1A shows the vertical JFET turned off, which can be a default mode of operation. As illustrated in FIG. 1A, the depletion regions 109 overlap at location 120 in the channel, preventing current flow through the channel region from the drain 101 to the source 106.

FIG. 1B shows the vertical JFET turned on, meaning the depletion regions 109 are separated, allowing current to flow in a vertical direction 110 from the drain 101 through the drift region 103 and channel region 108 to the source 106 when voltages V_{D} and V_{S} are applied to the drain contact 102 and source contact 107, respectively. In this embodiment, application of a voltage V_{G} applied to the gate 104 turns the vertical JFET on by decreasing the size of the depletion regions 109 and thereby providing a current path through the channel 108.

Whether the vertical JFET 100 is normally-on or normally-off can depend on different features of the vertical JFET 100, such as the width of the channel region 108, dopant concentrations in the channel region 108 and the gate 104, and the like. For example, a normally-on vertical JFET can be formed if the channel region is sufficiently wide and/or the dopant concentrations are high enough, in which case the depletion regions 109 may not pinch off the current when voltage V_{G} applied to the gate 104 is 0 V. The normally-on vertical JFET 100 can be turned off when V_{G} reaches a negative threshold voltage. Alternatively, for a normally-off vertical JFET, the channel is pinched off when V_{G} is 0 V, and the normally-off vertical JFET 100 can be turned on when V_{G} reaches a positive threshold voltage. It will be appreciated that a plurality of vertical JFETs can be provided in an array configuration to provide devices suitable for high current density operation. Additional description related to vertical JFETs with a regrown gate is provided in U.S. patent application Ser. No. 13/198,655, filed on Aug. 4, 2011, and entitled “METHOD AND SYSTEM FOR GAN VERTICAL JFET UTILIZING A REGROWN GATE,” the disclosure of which is hereby incorporated by reference in its entirety for all purposes.

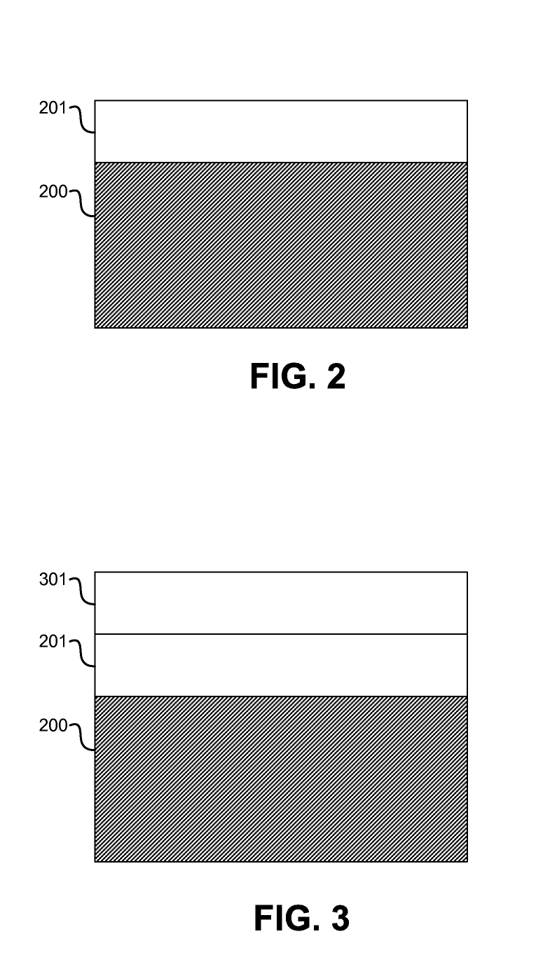

FIGS. 2-8 illustrate a process for creating a first type of vertical JFET that utilizes etching of an epitaxial layer to form the channel of the vertical JFET. As described more fully below, an etchback process is utilized to provide for spatial separation and electrical discontinuity between at least a portion of the gate material and at least a portion of the source material. In some embodiments, this vertical JFET is referred to as a vertical JFET with a regrown gate.

Referring to FIG. 2, a first GaN epitaxial layer 201 is formed on a GaN substrate 200. As indicated above, the GaN substrate 200 can be a pseudo-bulk GaN material on which the first GaN epitaxial layer 201 is grown. A buffer layer (not shown) can be utilized as will be evident to one of skill in the art. Dopant concentrations (e.g., doping density) of the GaN substrate 200 can vary. For example, a GaN substrate 200 can have an n+ conductivity type, with dopant concentrations ranging from 1×10¹⁷ cm⁻³ to 1×10¹⁹ cm⁻³. Although the GaN substrate 200 is illustrated as including a single material composition, multiple layers can be provided as part of the substrate. Moreover, adhesion, buffer, and other layers (not illustrated) can be utilized during the epitaxial growth process. One of ordinary skill in the art would recognize many variations, modifications, and alternatives.

The properties of the first GaN epitaxial layer 201 can also vary, depending on desired functionality. The first GaN epitaxial layer 201 can serve as a drift region for the vertical JFET 100, and therefore can be a relatively low-doped material. For example, the first GaN epitaxial layer 201 can have an n− conductivity type, with dopant concentrations ranging from 1×10¹⁴ cm⁻³ to 1×10¹⁸ cm⁻³. Furthermore, the dopant concentration can be uniform, or can vary, for example, as a function of the thickness of the drift region.

The thickness of the first GaN epitaxial layer 201 can also vary substantially, depending on the desired functionality. As discussed above, homoepitaxial growth can enable the first GaN epitaxial layer 201 to be grown far thicker than layers formed using conventional methods. In general, in some embodiments, thicknesses can vary between 0.5 μm and 100 μm, for example, thicknesses greater than 5 μm. Resulting breakdown voltages for the vertical JFET 100 can vary depending on the embodiment. Some embodiments provide for breakdown voltages of at least 100 V, 300 V, 600 V, 1.2 kV, 1.7 kV, 3.3 kV, 5.5 kV, 13 kV, or 20 kV.

Different dopants can be used to create n- and p-type GaN epitaxial layers and structures disclosed herein. For example, n-type dopants can include silicon, germanium, oxygen, or the like. P-type dopants can include magnesium, beryllium, carbon, zinc, or the like.

FIG. 3 illustrates the formation of a second GaN epitaxial layer 301 above the first GaN epitaxial layer 201. The second GaN epitaxial layer 301, which eventually comprises the channel of the vertical JFET 100, can have a low dopant concentration. In many embodiments, the dopant concentration of the second GaN epitaxial layer 301 can be equal to or less than the dopant concentration of the first GaN epitaxial layer 201, depending on the desired threshold voltage for the vertical JFET 100. Additionally, the second GaN epitaxial layer 301 can be the same conductivity type as the first GaN epitaxial layer 201. As discussed in relation to the first GaN epitaxial layer 201, and is as applicable to subsequent layers, adhesion layers, buffer layers, and the like, can be utilized during the epitaxial growth as appropriate to the particular device structure fabricated.

The thickness of the second GaN epitaxial layer 301 can also vary depending on the desired functionality. In some embodiments, thicknesses can be between 0.25 μm and 10 μm. In other embodiments, the thickness of the second GaN epitaxial layer 301 can be between 2 μm and 5 μm.

Similar to the first GaN epitaxial layer 201, the dopant concentration of the second GaN epitaxial layer 301 can be uniform or non-uniform. In some embodiments, dopant concentration can vary with the thickness of the second GaN epitaxial layer 301. For example, dopant concentration in the second GaN epitaxial layer 301 can increase as the distance from the first GaN epitaxial layer 201 increases. In other embodiments, the doping may be modulated between two or more values, or undoped regions, resulting in the desired average doping concentration for the layer. In some embodiments, the first epitaxial layer and the second epitaxial layer can be replaced by a single epitaxial layer providing both drift region and channel region functionality.

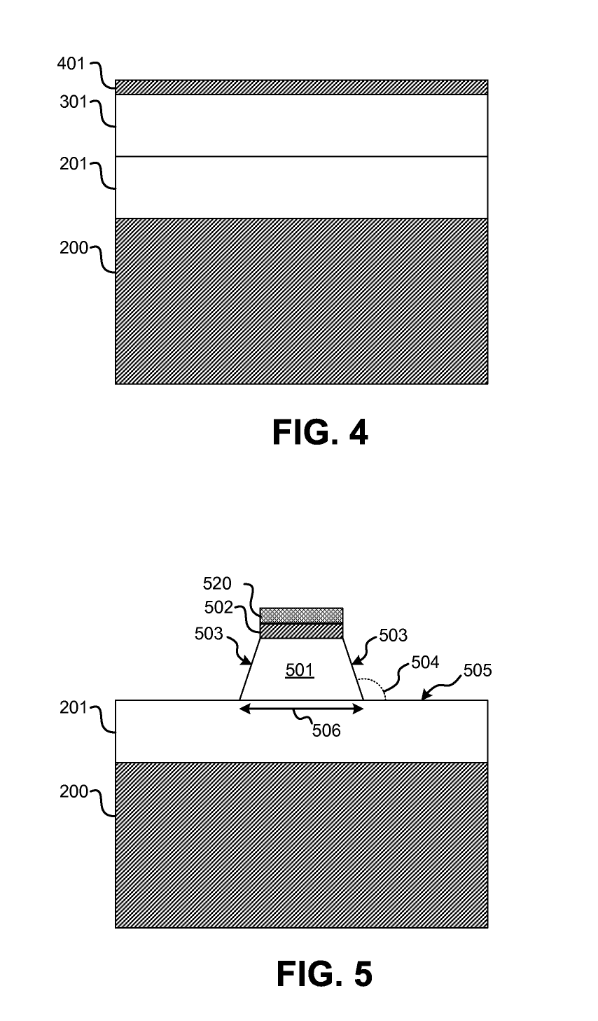

FIG. 4 illustrates the formation of a third GaN epitaxial layer 401 above the second GaN epitaxial layer 301. The third GaN epitaxial layer 401, which eventually can comprise the source of the vertical JFET 100, can be a highly-doped epitaxial layer of the same conductivity type as the first and second GaN epitaxial layers 201, 301. In general, the dopant concentration of the third GaN epitaxial layer 401 can exceed the dopant concentrations of the first and second GaN epitaxial layers 201, 301. For example, an n-type dopant concentration of the third GaN epitaxial layer 401 can be equal to or greater than 1×10¹⁸ cm⁻³.

The thickness of the third GaN epitaxial layer 401 can impact the contact resistance and current flow properties of the vertical JFET 100. In some embodiments, thicknesses can be between 500 Å and 5 μm, for example 2 μm. In other embodiments, the thickness of the third GaN epitaxial layer 401 can be 0.5 μm, or between 0.3 μm and 0.7 μm.

FIG. 5 is a simplified cross-sectional diagram illustrating the removal at least a portion of the second and third epitaxial layers to form the channel region and source region in the process of manufacturing the first type vertical JFET. As illustrated in FIG. 5, a mask 520 is formed and at least a portion of the second and third GaN epitaxial layers 301, 401 are removed to form the channel region 501 and source region 502 respectively. In embodiments utilizing a single epitaxial layer for the drift and channel regions, a portion of the single epitaxial layer is removed to form the channel region, leaving a portion of the single epitaxial layer in an as-deposited form. The removal can be performed by a controlled etch using an etch mask 520 having the dimensions of the source region 502 as illustrated in FIG. 5 and designed to stop at approximately the interface between the second GaN epitaxial layer 301 and the first GaN epitaxial layer 201. Due to the similarities between the first and second GaN epitaxial layers 201, 301, however, the etch may penetrate portions of the first GaN epitaxial layer 201 and/or fail to remove portions of the second GaN epitaxial layer 301 with negligible impact to the performance of the vertical JFET 100. Inductively-coupled plasma (ICP) etching and/or other common GaN etching processes can be used.

Depending on the processes used to form the channel region 501, the features of the resulting sidewalls 503 of the channel region 501 can vary. In some embodiments, the sidewall 503 can be vertical. In other embodiments, an outside angle 504 between the sidewall 503 and an upper surface 505 of the first GaN epitaxial layer 201 or other layer exposed by the removal process can be greater than 90 degrees, in which case the cross-sectional profile of the channel region 501 can be trapezoidal, as shown in FIG. 5. An outside angle 504 of greater than 90 degrees can facilitate deposition and/or regrowth of subsequent layers and can help improve performance by enabling better control of the electric field near the location where the sidewall 503 and upper surface 505 meet. In some embodiments, the removal profile (e.g., the etch profile) can produce a reentrant profile. One of ordinary skill in the art would recognize many variations, modifications, and alternatives.

The width 506 of channel region 501 (measured at the bottom of the channel) can vary, depending on numerous factors such as desired functionality of the vertical JFET 100, dopant concentrations of channel region 501, as well as other factors. For example, for a normally-off vertical JFET in which the channel region 501 has a dopant concentration between 1×10¹⁴ cm⁻³ and 1×10¹⁷ cm⁻³, the width 506 of the channel region 501 can be between 0.5 μm and 10 μm. In other embodiments, the width 506 of the channel region 501 can be less than 5 μm, less than 3 μm, less than 1 μm, or the like. For a normally-on vertical JFET, the width 506 of the channel region 501 can be greater.

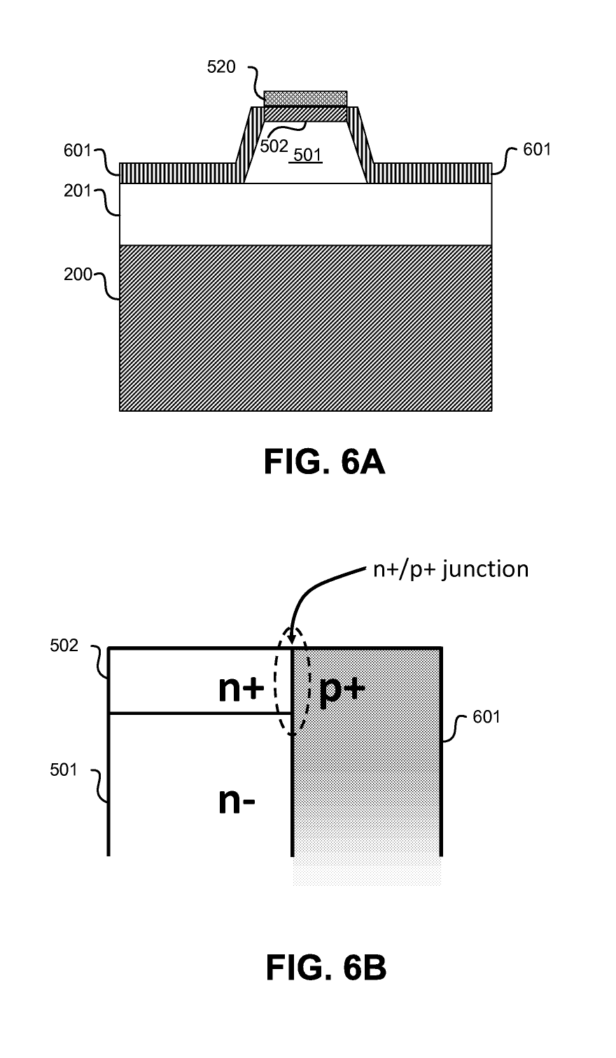

FIG. 6A illustrates the formation of a fourth GaN epitaxial layer 601. The fourth GaN epitaxial layer 601, which forms gate portions of the vertical JFET 100, has a conductivity type different than the channel region 501. For instance, if the channel region 501 is formed from an n-type GaN material, the fourth GaN epitaxial layer 601 will be formed from a p-type GaN material, and vice versa. In some embodiments, the layer 601 used to form the gate region is a continuous regrowth over portions of the device with other regions characterized by reduced or no growth as a result of the presence of a regrowth mask (not shown). As illustrated in FIG. 6A, mask 520 prevents regrowth on portion of the source region 502 (i.e., the top portion). In other embodiments, the regrowth is continuous over the entire substrate and then portions of the regrown layer are removed to expose the source region 502. One of ordinary skill in the art would recognize many variations, modifications, and alternatives.

The thickness of the fourth GaN epitaxial layer 601 can vary, depending on the process used to form the layer and the device design. In some embodiments, the thickness of the fourth GaN epitaxial layer 601 is between 0.1 μm and 5 μm. In other embodiments, the thickness of the fourth GaN epitaxial layer 601 is between 0.3 μm and 1 μm.

The fourth GaN epitaxial layer 601 can be highly doped, for example a magnesium acceptor concentration in a range from about 5×10¹⁷ cm⁻³ to about 2×10²⁰ cm⁻³. Additionally, as with other epitaxial layers, the dopant concentration of the fourth GaN epitaxial layer 601 can be uniform or non-uniform as a function of thickness. In some embodiments, the dopant concentration increases with thickness, such that the dopant concentration is relatively low near the first GaN epitaxial layer 201 and channel region 501 and increases as the distance from the first GaN epitaxial layer 201 and channel region 501 increases. Such embodiments provide higher dopant concentrations at the top of the fourth GaN epitaxial layer 601 where metal contacts can be subsequently formed.

One method of forming the fourth GaN epitaxial layer 601, and other layers described herein, can be through a regrowth process that uses an in-situ etch and diffusion preparation processes. These preparation processes are described in U.S. patent application Ser. No. 13/198,666, filed on Aug. 4, 2011, entitled “Method and System for Formation of P-N Junctions in Gallium Nitride Based Electronics,” the disclosure of which is hereby incorporated by reference in its entirety for all purposes.

FIG. 6B is a simplified magnified view of the source region and a portion of the regrown gate material according to an embodiment of the present invention. Referring to FIG. 6B, is can be noted that the fourth GaN epitaxial layer 601 is in contact (i.e., electrical contact) with the sidewalls of channel region 501 as well as the sidewalls of the source region 502. Thus, as illustrated in FIG. 6B, the p+ material of the regrown gate 601 makes electrical contact with n+ material of the source region 502. As a result, a lateral p-n junction is formed between these two materials. Depending on the doping concentration of the materials, particularly the source region 502, a Zener diode can be formed, resulting in tunneling current flowing between the gate and source and adversely impacting the performance of the vertical JFET. As will be evident to one of skill in the art, the illustrated structure thus presents undesirable gate leakage issues. As described more fully below, embodiments of the present invention utilize additional processing steps to remove the potential diode between the gate and source, improving the performance of the vertical JFET device.

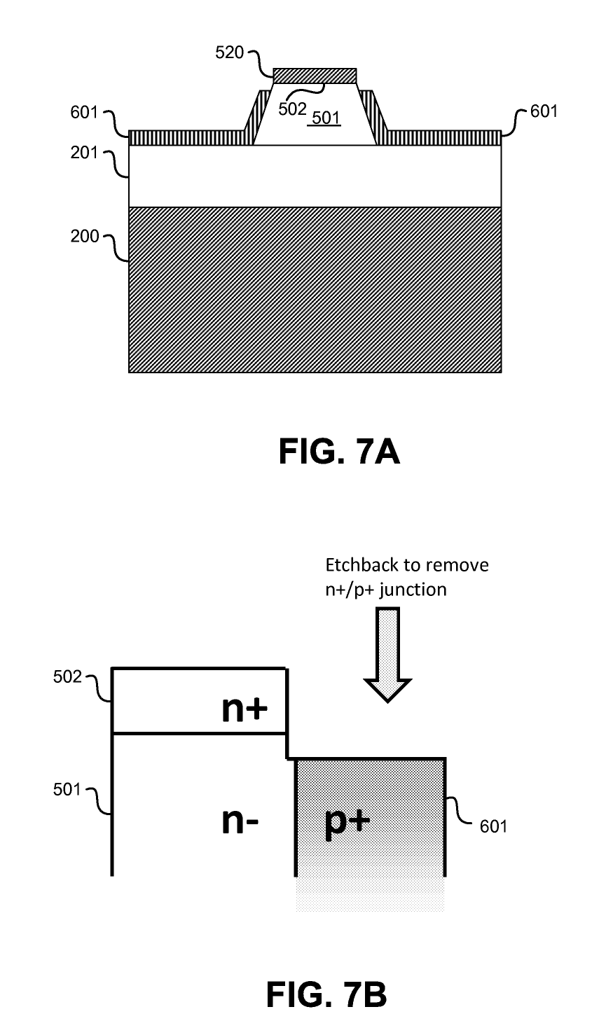

FIG. 7A illustrates the use of an etchback process to remove a portion of the regrown gate material according to an embodiment of the present invention. As illustrated in FIG. 7A, a portion of the regrown gate material 601 has been removed adjacent to the source region 502, preventing the formation of a diode between the heavily doped n+ source region 502 and the heavily doped regrown gate material 601. A p-n junction is still formed between the gate material and the channel region 501, enabling pinching off of the channel as discussed in relation to FIGS. 1A and 1B. At the same time, the heavily doped source region 502 remains and is used to provide a region to which an ohmic contact is formed as described below.

FIG. 7B is a simplified magnified view of the source region and a portion of the regrown gate material according to an embodiment of the present invention. Referring to FIG. 7B, is can be noted that the fourth GaN epitaxial layer 601 adjacent to the source region 502 has been removed to a level below the interface between the source region and the channel region 501, preventing electrical contact between the sidewalls of the source region 502 and the regrown gate material 601. The removal of the lateral p-n junction illustrated in FIG. 6B improves the performance of the vertical JFET by reducing undesirable gate leakage currents.

Referring to FIG. 7B, the etchback process can extend laterally into the source region 502 and the channel region 501. In other embodiments, the etchback process is self-aligned. Referring to FIG. 7B, the spatial separation between the source region and the gate regions includes both a vertical and a lateral component. The vertical component is equal to the vertical distance between the top of the gate structure and the bottom of the source region (i.e., the top of the channel region). The lateral component is a function of the sidewall angle of the channel region and the vertical component. In some embodiments, for example, embodiment in which the channel sidewalls are substantially vertical, only a vertical component may be present. In either case, the spatial separation provides for electrical isolation between the source and gate regions, reducing leakage currents and improving device performance. One of ordinary skill in the art would recognize many variations, modifications, and alternatives.

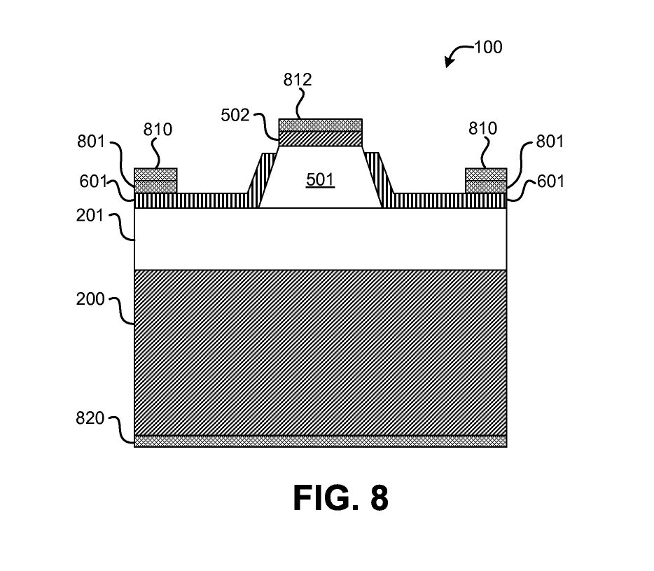

FIG. 8 illustrates the formation of electrical contacts to the terminals of the vertical JFET according to an embodiment of the present invention. As illustrated in FIG. 8, the formation of a metallic structure 820 below the GaN substrate 200 is provided. The metallic structure 820 can be one or more layers of ohmic metal that serve as a contact for the drain of the vertical JFET 100. For example, the metallic structure 820 can comprise a titanium-aluminum (Ti/Al) ohmic metal. Other metals and/or alloys can be used including, but not limited to, aluminum, nickel, gold, combinations thereof, or the like. In some embodiments, an outermost metal of the metallic structure 820 can include gold, tantalum, tungsten, palladium, silver, or aluminum, combinations thereof, and the like. The metallic structure 820 can be formed using any of a variety of methods such as sputtering, evaporation, or the like.

FIG. 8 also illustrates the formation of additional metallic structures 801 on the fourth GaN epitaxial layer 601. The additional metallic structures 801 can be one or more layers of ohmic metal including metals and/or alloys similar to the metallic structure 820. The additional metallic structures 801 are formed on the fourth GaN epitaxial layer 601 to serve as the gate contacts of the vertical JFET 100. The additional metallic structures 801 can be formed using a variety of techniques, including lift-off and/or deposition with subsequent etching, which can vary depending on the metals used. Example metals include nickel-gold (Ni/Au), palladium (Pd), platinum (Pt), and the like.

FIG. 8 additionally illustrates the formation of further metallic structures 810, 812 on the additional metallic structures 801 and the source region 502, respectively. These further metallic structures 810, 812 can be formed using the same techniques used to form the additional metallic structures 801 of FIG. 8, and also can include similar metals and/or alloys. The further metallic structure 812 formed on the source region 502 can serve as a source contact for the vertical JFET 100.

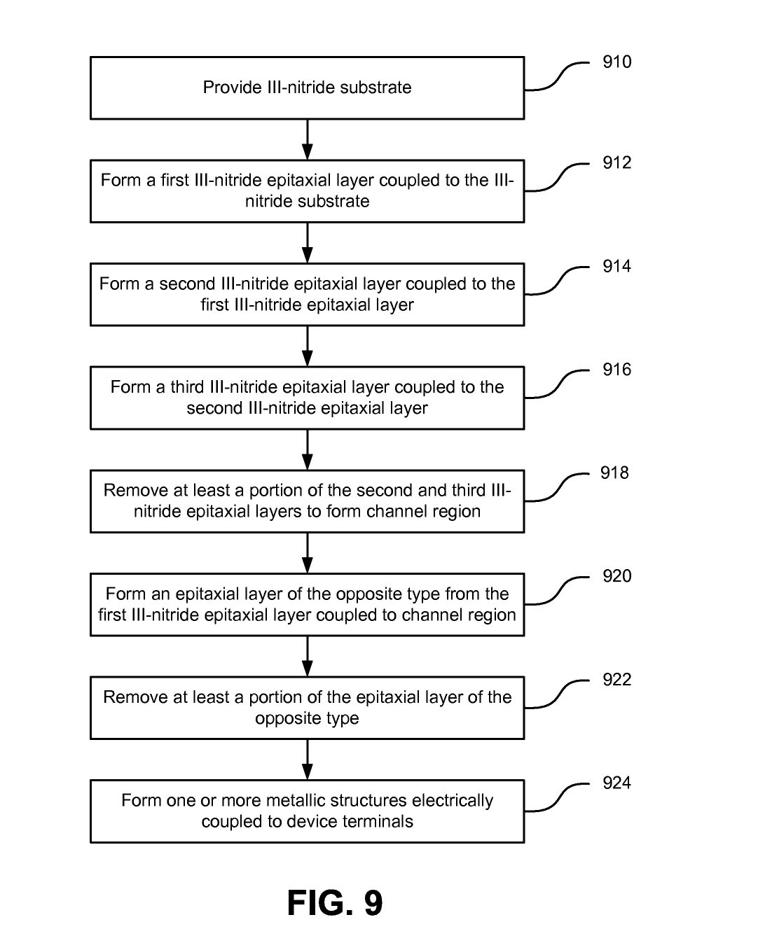

FIG. 9 is a simplified flowchart illustrating a method of fabricating a vertical JFET with separated source and gate regions according to an embodiment of the present invention. In some embodiments, the vertical JFET is referred to as a controlled switching device. Referring to FIG. 9, a III-nitride substrate is provided (910). In an embodiment, the III-nitride is an n-type GaN substrate. The method also includes forming a first III-nitride epitaxial layer (e.g., an n-type GaN epitaxial layer) coupled to the III-nitride substrate (912). The first III-nitride epitaxial layer is characterized by a first dopant concentration, for example n-type doping. Using the homoepitaxy techniques described herein, the thickness of the first III-nitride epitaxial layer can be thicker than available using conventional techniques, for example, between about 3 μm and about 100 μm, more particularly, between about 1 μm and 80 μm.

The method further includes forming a second III-nitride epitaxial layer (e.g., a GaN epitaxial layer) coupled to the first III-nitride epitaxial layer (914). The second III-nitride epitaxial layer has a second dopant concentration of the same type and less than or equal to the first dopant concentration, for example, n-type doping with a doping concentration lower than the first epitaxial layer.

The method includes forming a third III-nitride epitaxial layer (e.g., a GaN layer) coupled to the second III-nitride epitaxial layer (916). The third III-nitride epitaxial layer has a third dopant concentration of the same type and greater than the first dopant concentration, for example, an n-type layer with a higher doping concentration than the second epitaxial layer. The method further includes removing at least a portion of the third III-nitride epitaxial layer and at least a portion of the second III-nitride epitaxial layer to form a channel region of the second III-nitride epitaxial layer (918). The removal process can include a masking an etching process that can include physical etching components as well as chemical etching components.

Additionally, the method includes forming an epitaxial layer of an opposite type from the first III-nitride epitaxial layer (e.g., a p-type GaN layer) coupled to the channel region (920). This epitaxial layer forms a gate region at least partially surrounding the channel region previously fabricated. In order to provide for electrical isolation between the source and gate regions, at least a portion of the epitaxial layer of the opposite type is removed (922). As illustrated in FIGS. 7A and 7B, an etchback or other removal process can be used to remove the portions of the gate material in contact with the source, preventing the formation of a p-n junction between the gate material and the source material.

One or more metallic structures are formed that are electrically coupled to device terminals (924), for example, the drain, the source, and the gates. In an exemplary embodiment, a first metallic structure electrically coupled to the III-nitride substrate is formed as a drain contact, a second metallic structure electrically coupled to the epitaxial layer of the opposite type is formed as a gate contact, and a third metallic structure electrically coupled to the third III-nitride epitaxial layer is formed as a source contact. As illustrated in FIG. 8, these metallic structures provide for electrical connectivity to the drain, source, and gate of the vertical JFET. The various epitaxial layers do not have to be uniform in dopant concentration as a function of thickness, but may utilize varying doping profiles as appropriate to the particular application.

It should be appreciated that the specific steps illustrated in FIG. 9 provide a particular method of fabricating a vertical JFET with separated source and gate regions according to an embodiment of the present invention. Other sequences of steps may also be performed according to alternative embodiments. For example, alternative embodiments of the present invention may perform the steps outlined above in a different order. Moreover, the individual steps illustrated in FIG. 9 may include multiple sub-steps that may be performed in various sequences as appropriate to the individual step. Furthermore, additional steps may be added or removed depending on the particular applications. One of ordinary skill in the art would recognize many variations, modifications, and alternatives.

In an alternative embodiment, the etchback process is replaced by using a masking layer to cover the source region as well as a boundary region adjacent the source region. In this alternative embodiment, the regrowth mask covers the top and sides of the source regions, thereby preventing the regrowth of the gate material at locations adjacent the source, providing for electrical separation between the gate and source materials. Typically, the regrowth mask will be removed once the regrowth is completed. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for fabricating a controlled switching device, the method comprising:
providing a III-nitride substrate;
forming a first III-nitride epitaxial layer coupled to the III-nitride substrate, wherein the first III-nitride epitaxial layer is characterized by a first dopant concentration;
forming a second III-nitride epitaxial layer coupled to the first III-nitride epitaxial layer, wherein the second III-nitride epitaxial layer has a second dopant concentration of the same type and less than or equal to the first dopant concentration;
forming a third III-nitride epitaxial layer coupled to the second III-nitride epitaxial layer, wherein the third III-nitride epitaxial layer has a third dopant concentration of the same type and greater than the first dopant concentration;
removing at least a portion of the third III-nitride epitaxial layer and at least a portion of the second III-nitride epitaxial layer to form a channel region of the second III-nitride epitaxial layer;
forming an epitaxial layer of an opposite type from the first III-nitride epitaxial layer coupled to the channel region;
removing at least a portion of the epitaxial layer of the opposite type; and
forming one or more metallic structures electrically coupled to device terminals.

2. The method of claim 1 wherein forming the one or more metallic structures comprises:
forming a first metallic structure electrically coupled to the III-nitride substrate;
forming a second metallic structure electrically coupled to the epitaxial layer of the opposite type; and
forming a third metallic structure electrically coupled to the third III-nitride epitaxial layer.

3. The method of claim 1 wherein removing at least a portion of the epitaxial layer of the opposite type comprises removing portions of the epitaxial layer of the opposite type in electrical contact with the third III-nitride epitaxial layer.

4. The method of claim 1 wherein the first III-nitride layer comprises an n-type GaN epitaxial layer.

5. The method of claim 1 wherein a thickness of the first III-nitride epitaxial layer is between about 1 μm and about 100 μm.

6. The method of claim 5 wherein the thickness is between about 4 μm and 80 μm.

7. The method of claim 1 wherein the first III-nitride epitaxial layer is an n-type layer and the epitaxial layer of the opposite type is a p-type layer.

8. The method of claim 1 wherein at least one of the first dopant concentration, the second dopant concentration, or the third dopant concentration is non-uniform as a function of thickness.

9. A semiconductor structure comprising:
a III-nitride substrate;
a first III-nitride epitaxial layer of a first conductivity type coupled to the III-nitride substrate;
a first III-nitride epitaxial structure of the first conductivity type coupled to the first III-nitride epitaxial layer;
a second III-nitride epitaxial structure of the first conductivity type coupled to the first III-nitride epitaxial structure; and
a second III-nitride epitaxial layer coupled to the first III-nitride epitaxial structure, wherein the second III-nitride epitaxial layer is of a second conductivity type and is not electrically connected to the second III-nitride epitaxial structure.

10. The semiconductor structure of claim 9 wherein the second III-nitride epitaxial layer is spatially separated from the second III-nitride epitaxial structure by at least one of a vertical spacing or a lateral spacing.

11. The semiconductor structure of claim 9 wherein a dopant concentration of the first III-nitride epitaxial layer is between 1×10¹⁴ cm⁻³ and 1×10¹⁸ cm⁻³.

12. The semiconductor structure of claim 9 wherein the first III-nitride epitaxial layer has a thickness between 1 μm and 100 μm.

13. A vertical III-nitride field effect transistor comprising:
a drain comprising a first III-nitride material;
a drain contact electrically coupled to the drain;
a drift region comprising a second III-nitride material coupled to the drain and disposed adjacent to the drain along a vertical direction;
a channel region comprising a third III-nitride material coupled to the drift region;
a gate region at least partially surrounding the channel region;
a gate contact electrically coupled to the gate region;
a source coupled to the channel region and electrically isolated from the gate region; and
a source contact electrically coupled to the source;
wherein the channel region is disposed between the drain and the source along the vertical direction such that current flow during operation of the vertical III-nitride field effect transistor is along the vertical direction.

14. The vertical III-nitride field effect transistor of claim 13 wherein the first III-nitride material comprises an n-type substrate.

15. The vertical III-nitride field effect transistor of claim 13 wherein the second III-nitride material comprises an n-type GaN epitaxial layer having a dopant concentration less than or equal to a dopant concentration of the first III-nitride material and a thickness greater than 1 μm.

16. The vertical III-nitride field effect transistor of claim 13 wherein a width of the channel region measured along a direction orthogonal to a thickness of the drift region is less than 5 μm.

17. The vertical III-nitride field effect transistor of claim 13 wherein the gate region comprises a p-type III-nitride material.

18. The vertical III-nitride field effect transistor of claim 13 wherein the gate region is further electrically coupled to the drift region.

19. The vertical III-nitride field effect transistor of claim 13 wherein a spatial separation is present between the source and the gate region.

20. The vertical III-nitride field effect transistor of claim 19 wherein the spatial separation comprises at least one of a vertical component or a lateral component.
